(19) United States
(12) Patent Application Publication
(10) Pub. No.: US 2005/0012204 A1
(43) Pub. Date: Jan. 20, 2005

(54) High efficiency semiconductor cooling device

(76) Inventor: Richard Strnad, Dallas, TX (US)

Correspondence Address: Richard K. Robinson;ROBINSON & POST, LLP, North Dallas Bank Tower, Suite 575, 12900 Preston Road, LB-41, Dallas, TX, 75230, US

(21) Appl. No.: 10/300,044

(22) Filed: Nov. 19, 2002

Related U.S. Application Data
(60) Provisional application No. 60/400,152, filed on Jul. 31, 2002.

(51) Int. Cl. H01L 21/48; H01L 27/16

(52) U.S. Cl. 257/712; 257/713; 257/930; 438/125

(57) ABSTRACT

A semiconductor device has a cooling circuit located around a semiconductor circuit on the first surface. The cooling circuit includes a cooling cell with a semiconductor area of a second conductivity type and first and second conductors in parallel alignment, and located within the semiconductor area, and spaced apart from each other by a segment of the semiconductor area. The segment has a predetermined width, L, with the width L being predetermined so that the segment becomes substantially depleted when the cooling circuit is in operation.

This application relates to another patent application titled High Efficiency Semiconductor Cooling Device, filed on the same date, and claims the benefits of Provisional application 60/400,152.

### BACKGROUND OF THE INVENTION

### FIELD OF THE INVENTION

The invention relates generally to a thermoelectric cooling device and more generally it relates to a device that allows heat to be converted to electricity with efficiency approaching the efficiency of the electric transformers.

Thermoelectric devices have been in use for years. Number of domestic and foreign organizations are manufacturing and marketing thermoelectric devices. Applications vary from small consumer-type refrigerators to precise aerospace temperature control systems. A thermoelectric cooler or heater (thermoelectric module or thermoelectric device) is a component that functions as a small heat pump. By applying a DC voltage to a thermoelectric module, heat will be moved through the module from one end to another. One module end, therefore, will be cooled while the opposite end will be heated. This phenomenon is reversible, whereby a change in polarity will cause heat to be moved in opposite direction. Consequently, a thermoelectric device may be used for both heating and cooling thereby making it highly suitable for precise temperature control application. In view of this definition and for readability the term “thermoelectric cooler” shall be generic, and mean either a heater or cooler.

Views of a few commercially available thermoelectric devices are presented in FIGS. 1, 2 and 3.

In FIG. 1 there is shown a four stage thermoelectric device 10 reaching temperatures of −120° C. The device shown in FIG. 2 is a three stage thermoelectric device 17 producing temperature of about −90° C. with a small load and in FIG. 3, there is depicted a single layer thermoelectric device 17 capable of producing negative temperature of −40° C. Thus, it is the amount of cooling produced by a device that is dependent on the number of stages.

In FIG. 4 there is presented a view of a single thermoelectric device. FIG. 4a illustrates an upper supporting ceramic plate 16 onto which a conductive pattern 17 is deposited and highlighted in FIG. 4b. FIG. 4c shows an array of “p” and “n” types of thermoelectric columns 18, which are electrically connected by deposited conductive patters 17 and 19. Plate 20 of FIG. 4e is the bottom plate, which carries the conductive layer from array of “p” and “n” types of thermoelectric columns. And FIG. 4f shows a composite view of device assembly 21.

Thermoelectric energy conversion is the interconversion of heat and electrical energy for power generation or heat pumping and is based on the Seebeck and Peltier effects. In the early 1950s, progress led to the development of semiconductor thermo elements with the results that reasonably efficient thermoelectric devices could be constructed. Metallic thermocouples provide only very low efficiencies, the most favorable being combination of bismuth and antimony, which provide efficiencies of approximately 1%; selected semiconductors can provide efficiencies of approximately including 8-10%.

The independence of size vs. efficiency, the absence of moving parts, high reliability, quietness, lack of vibration, low maintenance, simple startup, and absence of pollution problems characterize the technique of direct energy conversion. Thermoelectric generators have been used in specialized applications in which combinations of their desirable features outweigh their high cost and low generating efficiencies, which are typically 3-7%. Large-scale thermoelectric generators cannot compete with oil-fired central power stations, which operate at efficiencies of 35-40%.

The most advanced thermoelectric systems are the Radioisotope Thermoelectric Generators (RTGs), which have been developed for military and space systems under the aegis of the US Department of Energy DOE. The RTGs most recently operated in space were used to power the Voyager I and II spacecrafts and have conversion efficiencies of 6.7% and specific powers of 4.2 W/kg. Other RTGs have been used for such applications as floating and terrestrial weather stations, cardiac pacemakers, and navigational buoys. Fossil-fired thermoelectric generators have been developed for military and commercial applications. Some of these applications include power for remote navigational lights, communication line repeaters, and cathodic protection, eg, protection of the east-west pipeline across Saudi Arabia by 34 thermoelectric stations.

Thermoelectric heat pumping, like thermoelectric power generation, has increased applications in those areas where the advantages of the thermoelectric conversion process, i.e., small space, lightweight, high reliability, no noise or pollution, and simple temperature control, can be utilized.

Thermoelectric cooling devices have been developed for a variety of military and commercial applications. These include submarine air-conditioning systems, small refrigerators, and recreational instruments, and cooling for electro-optical systems. They could be used in systems using night navigation, night vision cameras, in the navigation of long and short-range rockets, missiles and other instruments of war.

Peltier Cooling is the textbook interpretation of the inner working of thermoelectric cooling.

The principle of operation of a Peltier device is shown in FIGS. 5, 6 and 7. In FIG. 5 there is shown an assembly 51 of p and n type semiconductor 52 and 53 respectively and two metallic plates 54 and 55. When a battery 56 is connected to both semiconductor columns 52 and 53 via metallic plates 54 and 55, a passage of current will produce cooling and heating effects for given current polarity, as is shown in FIG. 6. With the positive thermal applied to the p type semiconductor, the positive end is coded and the end that the negative terminal is connected in order to be heated, and the reverse will occur for the n type semiconductor 53. When reversed, polarity is applied by battery 57, previously hot ends will turn cold and the previously cold ends will turn hot, as viewed in FIGS. 6 and 7.

Detailed views of events just described are given in FIGS. 8, 9, 10, 11, 12 and 13. The role, that Joule's heat is playing, is intentionally omitted.

Although the Peltier cooling and Seebeck electricity generation is not exclusive to semiconductors, the band diagram structure for p and n type semiconductors is highlighted in FIGS. 14, 15 and 16.

Current understanding of the Peltier effect principle is explained on bases of moving electrons or holes from one material to another and electrons or holes are said to be the carriers of heat. It was found that the quantity of heat transferred is proportional to the quantity of electricity flowing. The constant of proportionality is the differential Peltier coefficient, α_{P}_{_{ab}}, given by

$${α}_{{P}_{ab}} = \frac{W}{Q} = \frac{P}{I} volts \qquad ( 1 )$$

Where W is the energy in joules transferred to or from the junction between two materials, a and b, by a charge of Q coulombs, α_{P}_{_{ab}} is often more conveniently expressed in terms of the power P (watts) transferred by a current I (amperes).

If the two materials are joined at two points held at different temperatures, an open-circuit potential difference ΔV is produced as a result of a temperature difference ΔT between the junctions, the Seebeck effect. This leads to the differential Seebeck coefficient, α_{S}_{_{ab}}, given by:

$${α}_{{S}_{ab}} = {lim}_{Δ T \to 0} \frac{Δ V}{Δ T} V \text{/} ° C \qquad ( 2 )$$

The e.m.f. generated when ΔT=31 1° C. is sometimes called the thermoelectric power. The two coefficients (and) are related by relationship:

$${α}_{{S}_{ab}} = \frac{{α}_{{P}_{ab}}}{T} \qquad ( 3 )$$

Where T is the absolute temperature of the cold junction.

Finally, where there is a temperature difference ΔT over part of a single conductor the passage of current I leads to thermal power ΔP being generated. This is an event, related to the Peltier and Seebeck effect, and is not considered.

The junction of two metals to form a thermocouple has been used for a long time as a method of measuring temperature, with copper-constantan or iron-constantan couples having values of α_{S} up to about 50 μV/° C. Correspondingly low values of α_{P} occur, so that little energy is transferred when a current is passed through the junction, with a consequently small cooling effect. This is because the conduction electrons all have energies close to the Fermi level, and very small energy changes occur when a current flows through the junction. However, for the ohmic contact between a metal and a non-degenerate semiconductor α_{P} is much larger and a significant cooling effect may be obtained.

Consider an n-type semiconductor section 81 sandwiched between two metals 82 and 83 respectively to form two ohmic contacts (FIG. 8). If a potential difference is applied as shown, only the higher energy electrons in metal 82 will be able to move over the potential barrier φ_{S}-χ into the semiconductor 81 (FIG. 9). Thus in metal 83 the average electron energy is reduced, while in metal 82 it is increased, so that heat is transferred from metal 82 to metal 83. If a p-type semiconductor is substituted and the same voltage applied (FIG. 10), a hole current will flow due to movement of electrons in the valence band under the potential barrier ζ-φ_{S}. Thus low-energy electrons are removed from metal 1, increasing its average energy and reducing the average energy of metal 2, so that heat is obtained from the energy diagram, since the electrons crossing from metal 82 to an n-type semiconductor 81 possess potential energy (φ_{S}-χ) and mean kinetic energy \overline{w}, which is proportional to

$${α}_{{P}_{mn}} = - \frac{\overline{w + ( {ϕ}_{S} - χ )}}{e} \qquad ( 4 )$$

The minus sign indicates removal of energy from the metal. Similarly, for a metal-to-p-type semiconductor contact,

$${α}_{{P}_{mp}} = + \frac{\overline{w + ( ζ - {ϕ}_{S} )}}{e} \qquad ( 5 )$$

The plus sign indicating energy transfer to the metal 83, due to the temperature dependence of the quantities in eqs. (4) and (5) α_{P} rises with temperature.

A commercial cooling device is obtained by arranging n and p type materials in couples (FIGS. 1, 2 & 3). The passage of current due to the indicated applied voltage will cause all the top metal surfaces to be cooled and the lower ones to be heated, while reversal of the current will cause reversal of the direction of the heat flow. Thus if one side of the device is fixed to a suitable heat sink maintained at room temperature, refrigeration of an article to the other side would occur. A p—n bismuth—telluride couple has a Seebeck coefficient of about 400 μV/° C. and for a well heat-insulated device with 16 couples, for example, a current of 10 A will cause a heat flow of about 3 W, maintaining a temperature difference of about 30° C. between the two surfaces. From eq. (1) the higher the current passed through the device the greater will be the rate of the heat flow, but a limit is by the heat dissipation due to the electrical resistance of the device and by the heat flowing in from the surroundings. It may be shown that the Joule heat produced in the resistance flows equally to the hot and cold surfaces, so that for a cooling unit of resistance R with the cold surface at temperature T_{c}, the equation governing the thermal condition of the load is

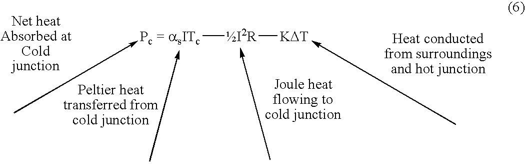

K is the thermal conductance of the device, which is reduced by efficient thermal insulation, and ΔT is the temperature difference between the surfaces. A high value of α_{S} is desirable to give as large a drop in temperature as possible for a given current; α_{S} is used in the above equation since it is less dependent on temperature than α_{P}.

The suitability of a material for use as a thermoelectric device depends on the above considerations and may be deduced from a figure of merit, Z given by

$$Z = \frac{{α}_{s}^{2}}{RK} {kelvin}^{- 1} \qquad ( 7 )$$

At room temperature, for metal junction Z is about 0.1×10⁻³ K.

### SUMMARY OF THE INVENTION

In view of the foregoing disadvantages inherent in the known types of thermoelectric type devices now outlined in the prior art, the present invention provides a thermal pocket cooling device construction wherein the same can be utilized for cooling objects, space, system or devices.

The general purpose of the present invention is to provide a new cooling device that has many of the advantages of the thermoelectric devices mentioned heretofore and many novel features that result in a new cooling device.

To attain this, the present invention generally comprises a device converting moving electric charges into thermal pockets. The main component is a junction of dissimilar materials, such as metal and p-type semiconductor, metal and n-type semiconductor, metal to metal junction, p-type semiconductor to n-type semiconductor junction, p-type or n-type semiconductor to inversion layer junction, metal to p-type and n-type semiconductor junction and other combinations thereafter. This is achieved by making the thermal conductance K and the thermal resistance as small as possible.

A primary object of the present invention is to provide a cooling device that will overcome the shortcomings of the prior art devices.

An object of the present invention is to provide a thermal device for cooling of objects, space, system or devices.

Another object of the invention is to incorporate cooling device into to body of integrated circuits.

Another object of the invention is to provide cooling of the substrate, which is used as a mounting and supporting carrier and as a cooling device to subsystems, attached to this substrate.

Another object of the invention is to yield high efficiency, low cost, lightweight for portability, easy to use device.

Another object of the invention is to provide low temperature environment for superconducting devices, high heat output components, integrated circuits and superconductive systems.

Another object of the invention is to provide a cooling system that may be used to control temperature of precision voltage standards, voltage references, A/D converters, D/.A converters, amplifiers, comparators and other analog devices.

Another object of this invention is to provide a low temperature for devices used in low light level cameras, infrared detections systems, UV systems, and weaponry.

Another object of this invention is to provide low temperature environment for high-speed circuits, communication devices, digital processors and computing devices.

Another object of this invention is to provide accurate low temperature in CCD and MOS cameras.

Other objects and advantages of the present invention will become obvious to the reader and it is intended that these objects and advantages be within the scope of the present invention.

### BRIEF DESCRIPTION OF THE FIGURES

FIGS. 1-4 illustrate prior art thermoelectric devices.

FIGS. 5-7 illustrate a prior art Peltier device.

FIGS. 8-13 illustrate detailed views of the operation of the Peltier device.

FIGS. 14-18 illustrate the band diagram structure of the Peltier device.

FIG. 19 illustrates a single-stage cooling device.

FIG. 20 illustrates the cooling effect of the device.

FIG. 21 illustrates a pyramid structure of the prior art of FIGS. 1-3.

FIG. 22 illustrates a top view of a circular cooling device.

FIG. 23 illustrates a sectional cut of the device of FIG. 22.

FIGS. 24-25 illustrate sectional views of the cut of FIG. 22.

FIGS. 26(a-d) illustrate the progression of additional ring segments.

FIGS. 27(a-b) illustrate stacked cells separated by insulators.

FIG. 28 illustrates a gas heater, including a pipe.

FIG. 29 illustrates the device of FIG. 28 with additional cooling.

FIG. 30 illustrates an application of the cooling device according to this invention.

FIG. 31 shows a segment of the thermoelectric cooling circuit.

FIG. 32 shows use of the thermoelectric cooling device of this invention on a high power transistor switch.

FIG. 33 shows an alternate embodiment of the invention.

FIG. 34 shows another alternate embodiment of the invention.

FIG. 35 shows a frontal view of an infrared lense with the cooling device of this invention.

FIG. 36 shows a frontal view of either a spacecraft of underwatercraft with the cooling device of this invention.

FIG. 37 is a table of components.

### DETAILED DESCRIPTION OF THE INVENTION

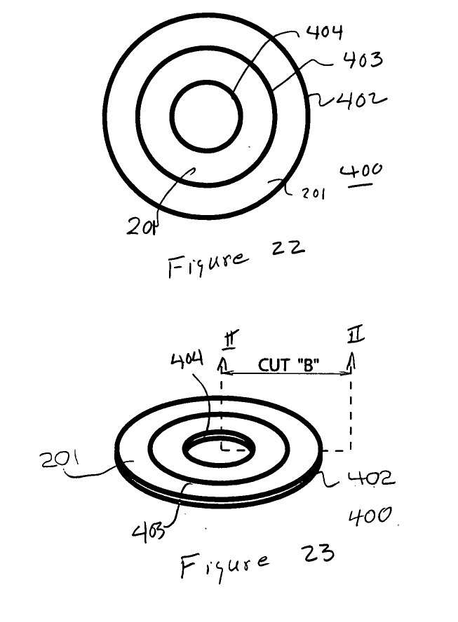

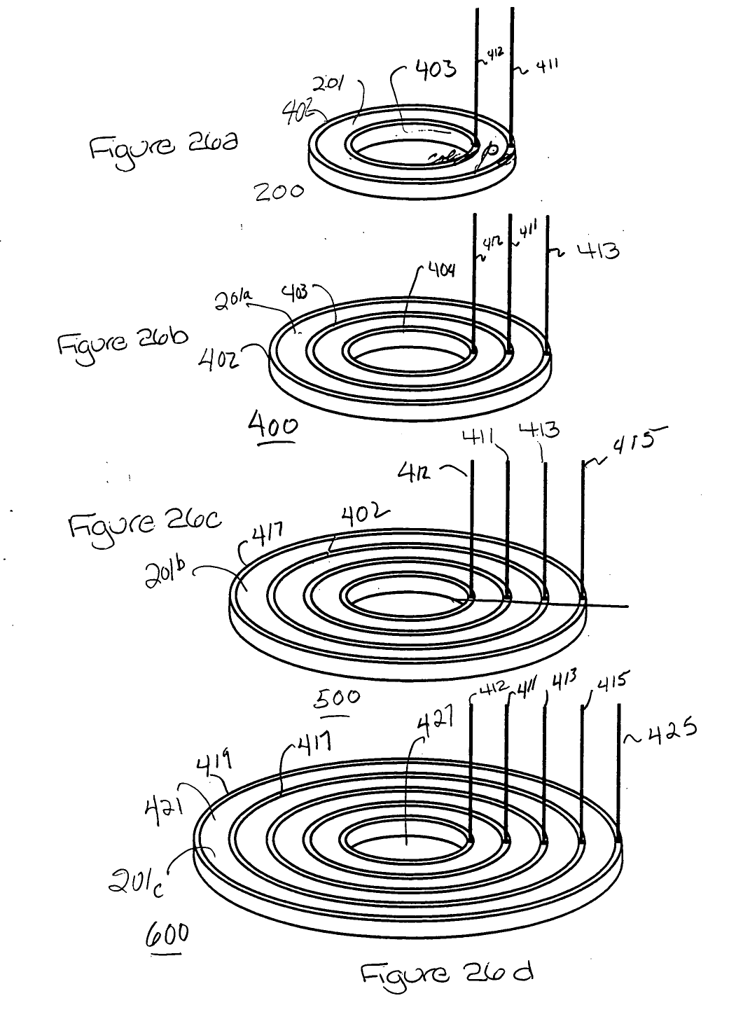

Equation (6) implies that the best results are achieved when the Joule's heat and the ΔT and K components are minimized. The Joule's heat reduction could be achieved by making the device short to minimize the resistance R. This is illustrated in FIGS. 11 through 21 for n- and p-type materials. In FIGS. 14 and 18 the Joule's heat is negligible due to the reduced length of material. The Peltier heat flow from one end to another becomes

$$\dot{Q} = \frac{ⅆ Q}{ⅆ τ} = - kA \frac{ⅆ θ}{ⅆ l} \qquad ( 8 )$$

The derivative

$$\frac{ⅆ θ}{ⅆ l}$$

is called the temperature gradient. The minus sign is introduced in order that the positive direction of the flow of heat should coincide with the positive direction of l. For heat to flow in the positive direction of l, this must be the direction in which θ decreases.

The Equation (8) deals with transport of heat from one junction to another.

When the current is applied to a cell, each end of the material is maintained at different temperature and empirical measurements will show a continuous distribution of temperature. The transport of energy between neighboring volume elements is by virtue of the temperature difference between the elements and is known as heat conduction. The fundamental law of heat conduction is a generalization of the results of experiments on the linear flow of heat through a slab perpendicular to the faces. If a device is made from a slab of silicon of thickness Δx and of area A and one junction is maintained at the temperature θ and the other at θ+Δθ. The heat Q that flows perpendicular to the faces for a time τ is measured. It is a time unit.

FIGS. 11-18 provide a detail explanation of the operation of the invention. Beginning with FIG. 11 there is shown a representation of a piece of p-type semiconductor material 109 that has a length of 31 as represented by dimension lines 308. There is a metal plate 102 on one end and opposite the metal plate and separated by the distance 31 is a second metal plate 103 at the opposite end of the p-type semiconductor material 109. There is a constant current source 105 provided and when a switch 141 is closed current would flow from the current source 105 through plate 103 the p-type semiconductor material 109 and then through plate 102 back to the current source 105.

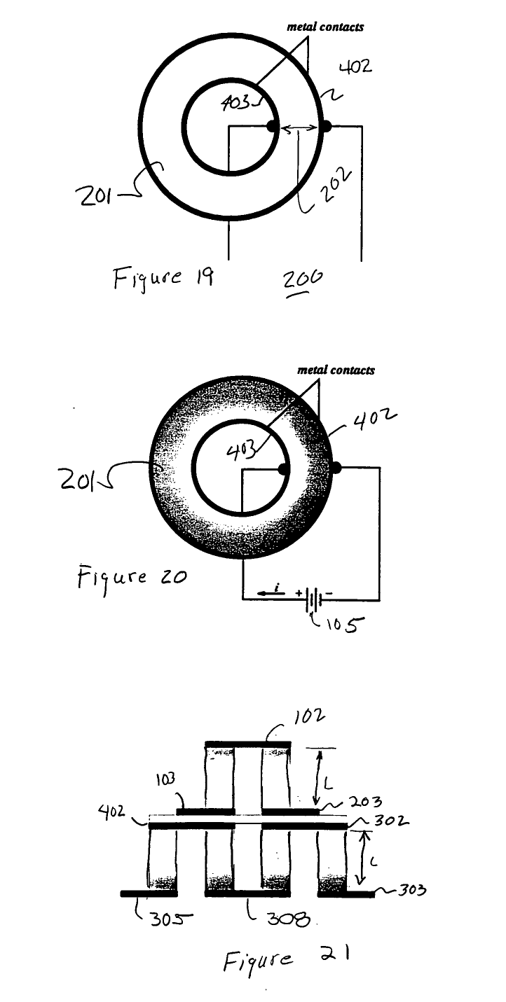

FIG. 12 illustrates the situation where the switch 141 is in the closed position and current is flowing as indicated by arrow 110 from the constant current supply 105. There is heat present and a depletion region 109 is generated by the effects of the heat on the semiconductor bar 109. Similarly, there is a depletion region 113 that is present that is caused by the electric field created by the flow of the current A, between plates 103 and 102.

In FIG. 13, as was in FIG. 12, there is an area 114 that is also heated by the effect of the joule heating that is the results of the internal resistance of the p-type semiconductor material 109.

Referring to FIG. 14, the plates 103 and 102 have been positioned so that the depletion region created by the heat next to the plate 102 is overlapping the depletion region created by the electric field created by the flow of current A into the plate 103. Thus, the separation of the plate 102 by the plate 103 is determined by length L of the p-type semiconductor material 109 where L ideally should be the depletion of the p-type semiconductor material 109 when the cooling device 900 is in use.

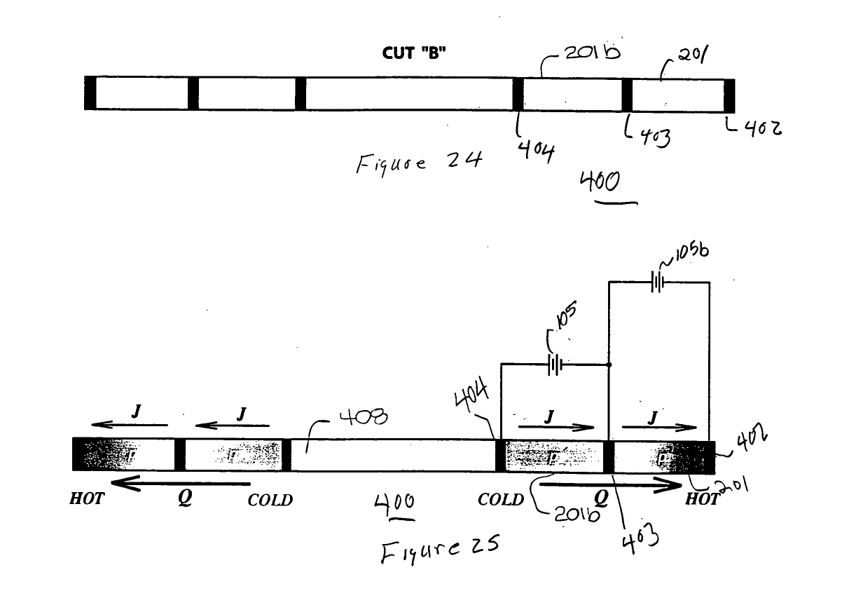

The removing of the joule heating area 114 from the circuit will enable the cooling circuit to function more efficiently due to the fact that the joule heating that is produced by the internal resistance has been minimized or eliminated. Therefore, in designing a heating or cooling system according to the invention, it would always be beneficial to ascertain the anticipated depletion region that is caused by the amount of heat to be removed and the depletion region that was generated/caused by the electric field generated by the current provided by the constant current supply 105. If n-type semiconductor material 161 should be selected, FIGS. 15-18 will demonstrate the similar results, wherein FIG. 15 the n-type material 161 is separated by the length of 31 between metal plates 102, 103. The constant current supply 105 is conductive such that the current I flows in the opposite direction. FIG. 16 shows the situation where the switch 141 is closed and there is a depletion region 133 primarily produced by the heat as well as a depletion region 129 that is next to the plate 103. Additionally, there is the area of 114 that is caused by the resistance to the current that flows through the bar 161. Finally in FIG. 18 the plates 102 and 103 are positioned between the p-type semiconductor material 115 such that the depletion regions are merged and the closeness of the plates enables the cooling effect of the circuit to be more effective.

FIG. 19 illustrates a single stage-cooling device that has an outer metal contact 402 and an inner metal contact 403. The metal contacts are separated by medium 201. The medium material could be in any state or vacuum, or it could be a semiconductor, a conductor, a liquid, it could be in solid state or plasma.

In the embodiment shown, and as was discussed in conjunction with equations 4 and 5 the selection of the material is based on the Peltier constant which determines the separations between the metal contact represented by arrow 202. The shape of the cooling article of FIG. 19 is circular however; it could be any polygonal shape, circular, elliptical, parabolic, hyperbolic, cercal, parabolic, or rotating hyperboloid. The application is not dependent on the shape.

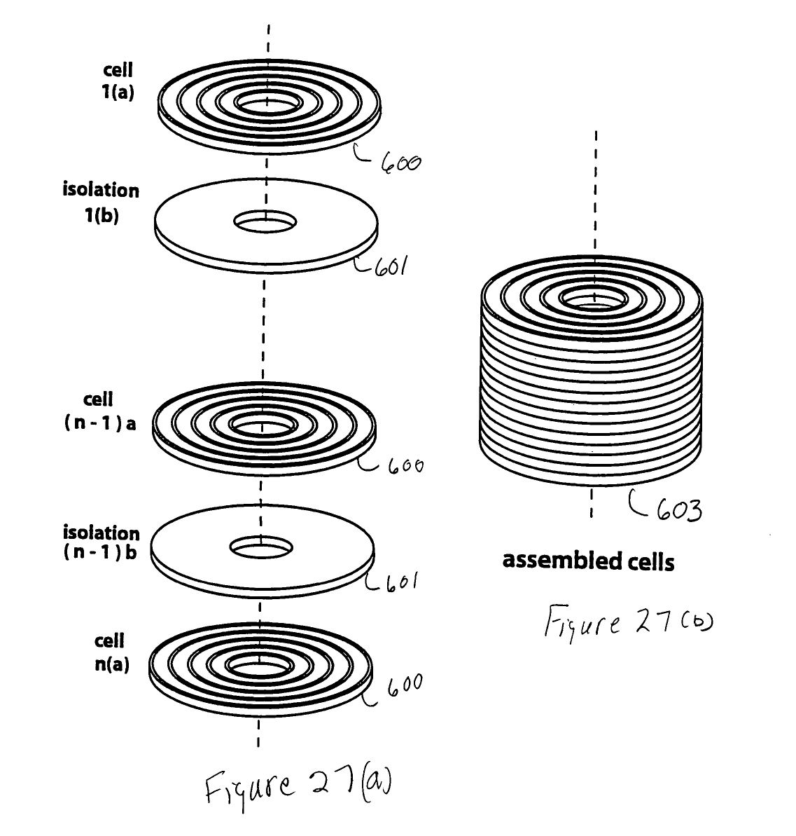

FIG. 20 illustrates the cooling effect of the device 200 showing where the metal contact 402 is heated or the hot contact and the internal contact 403 is the cold contact. The separation is the depletion region of medium 201.

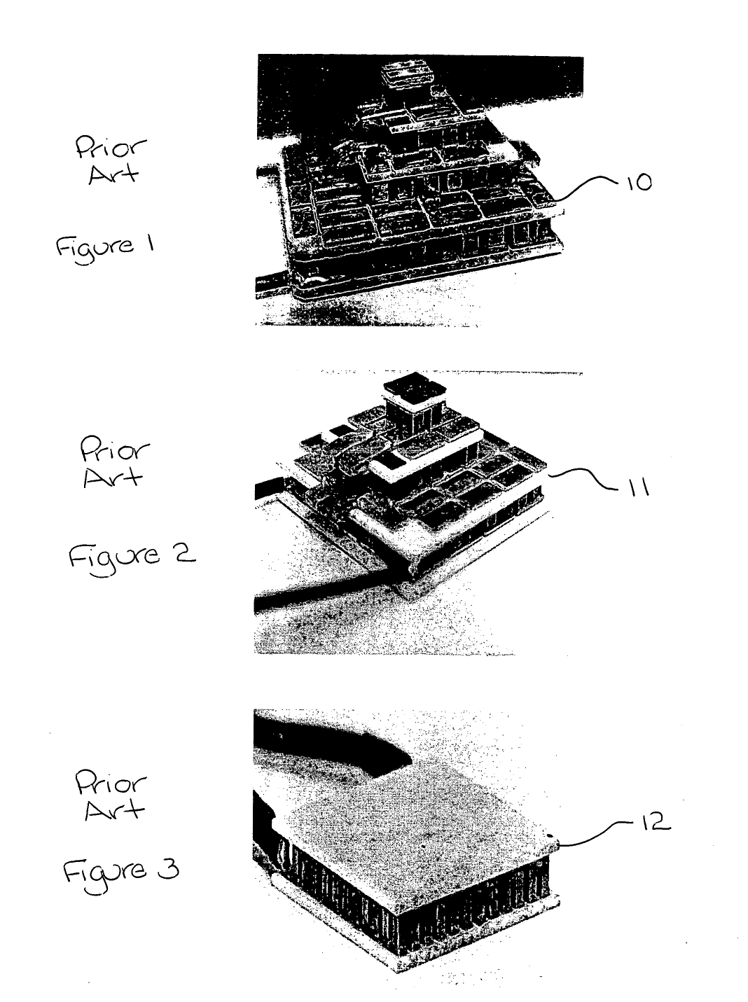

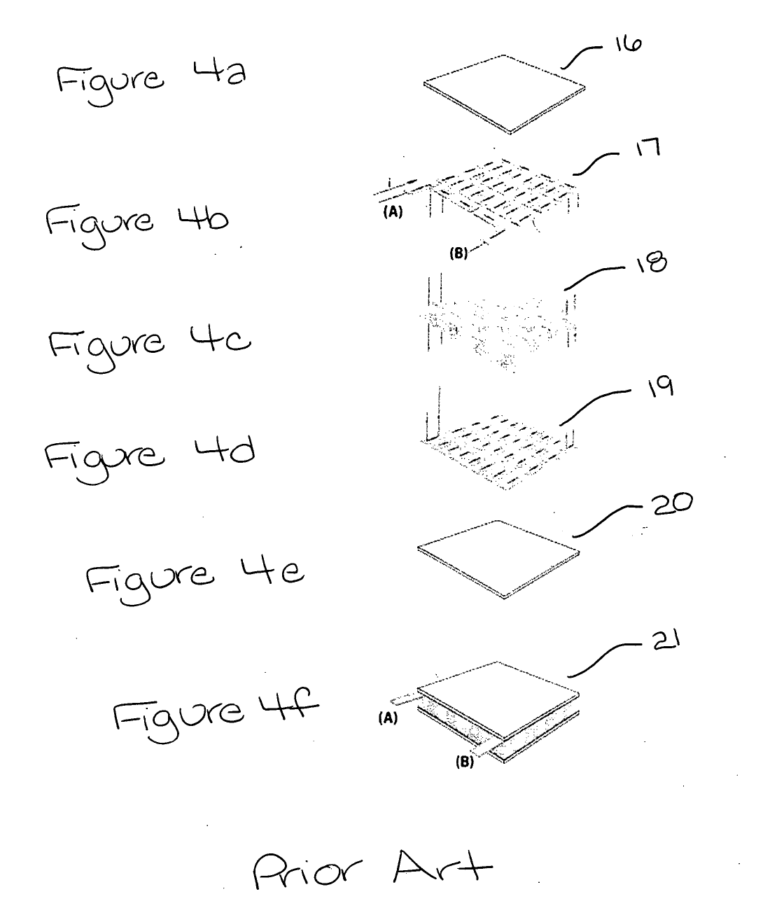

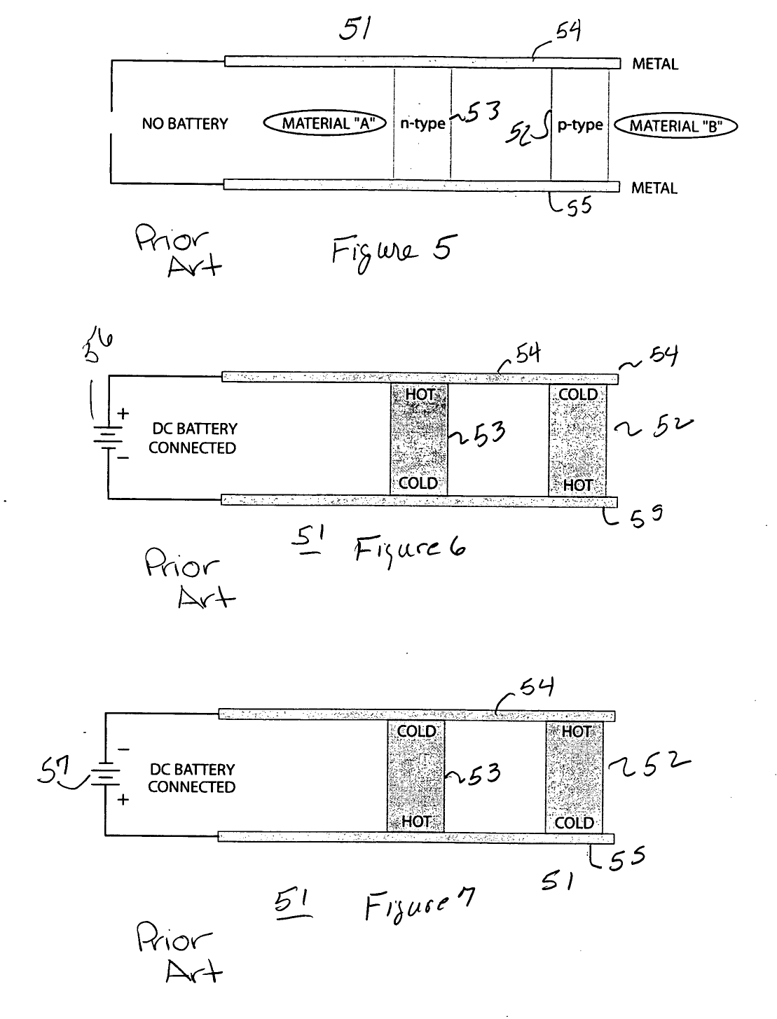

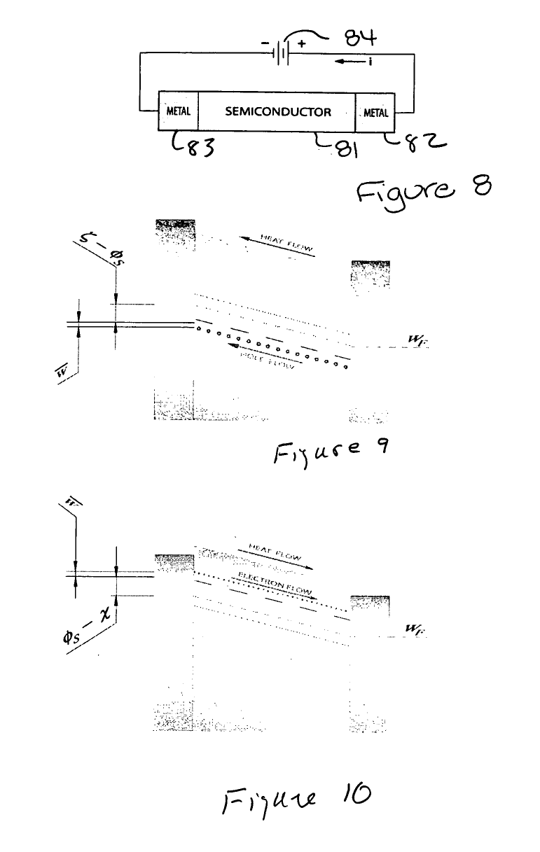

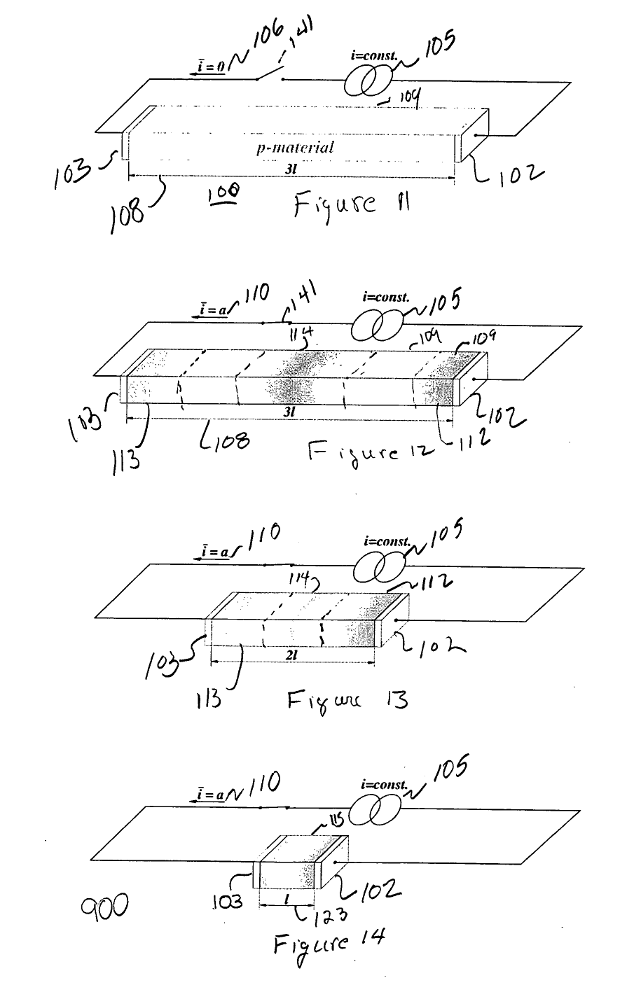

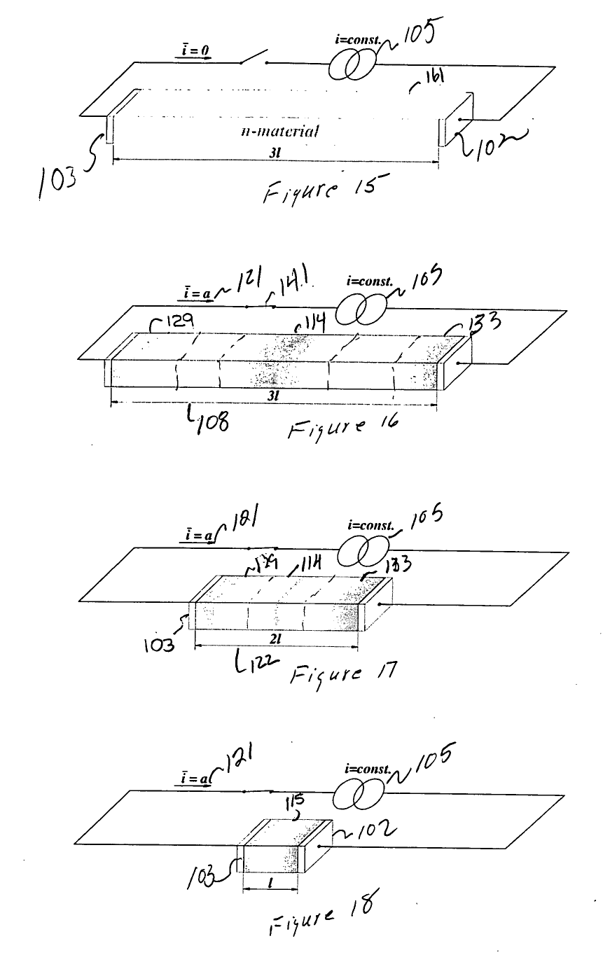

FIG. 21 illustrates the pyramid structures similar to those of FIGS. 1-3 disclosed in the prior art. The difference is that plate 102 is separated from plate 203 by the link L which has a link chosen to put the plates in contact with the depletion regions. Same is true for plate 103. Additionally, the stack pyramid also has a plate 302 separated by plate 303 by distance L, and plate 302 is separated by plate 308 by the distance L similarly plate 402 is separated from plate 305 by the distance L. These distances are chosen to be minimum so that the joule heating effect of the current flowing through the respective semiconductor regions is minimized.

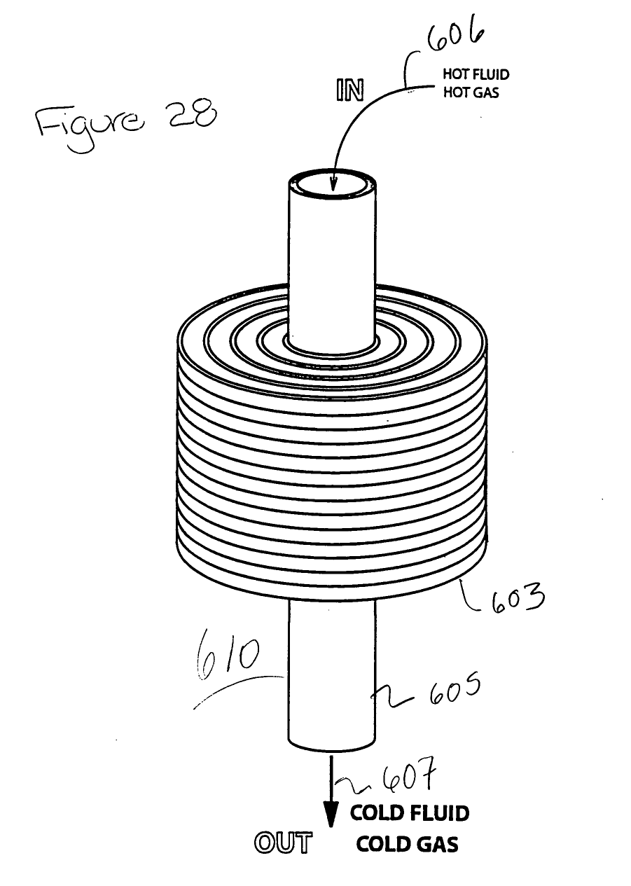

FIG. 22 shows a top view of a cooling device that is circular in shape. The device 400 has dual stages, which- approximately allows a doubling of the cooler effect over the device of FIG. 19.

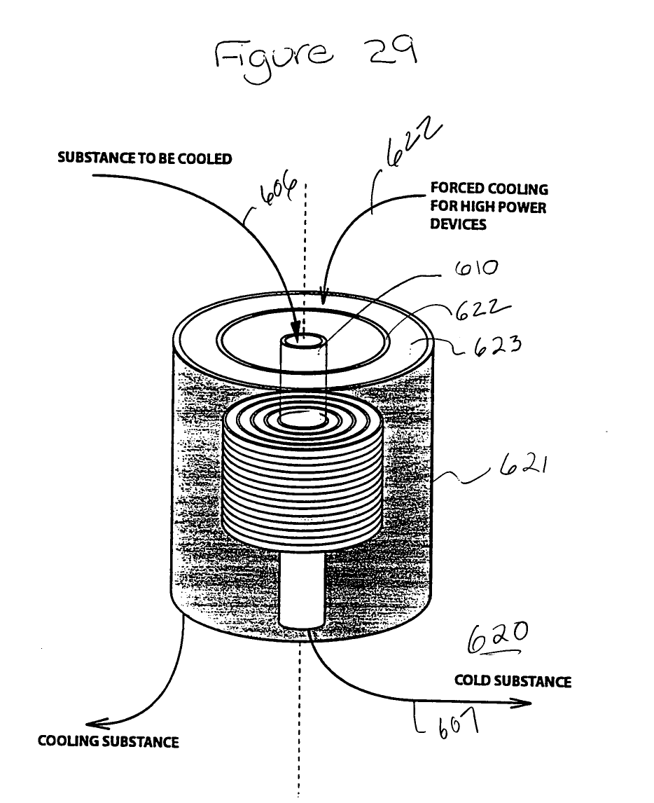

FIG. 23 shows a sectional cut made to the cooling device 400 and the sectional view is provided by FIG. 24.

Referring to FIG. 24 there is a metal plate 402 and a second metal plate 403 that are separated by a medium such as a semiconductor element 201. Similarly, metal contact 403 is separated by a metal contact 404 by an identical medium 201b, such as a p-type semiconductor material. If current is applied to the device 400 it would effect cooling as shown in FIG. 25. The positive terminal of current source 105 is applied to plate 404 and a current loop is completed via the current flowing through the p-type semiconductor device 201B to plate 403 or metal conductor 403 back to the negative terminal of battery 105. Current source 105b provides current to plates 403, which flows through the semiconductor device 201 to plate 402, and back to the terminal 105b. The current provided by current source 105b is double that of current source 105. This doubling increases because the segment that includes plate 403, semiconductor segment 201, and plate 402 will have to remove twice the heat as the device that comprises the metal plate 404, semiconductor 201b, and metal plate 403. Since the semiconductor regions have the same lateral dimensions, the outer most region must cool both itself and all outer regions including the center one 408. The total number of regions in FIG. 25 is 3, so the author states would have to remove 2 times the heat of the minus stage ie I (n-1) unless n is the number of regions.

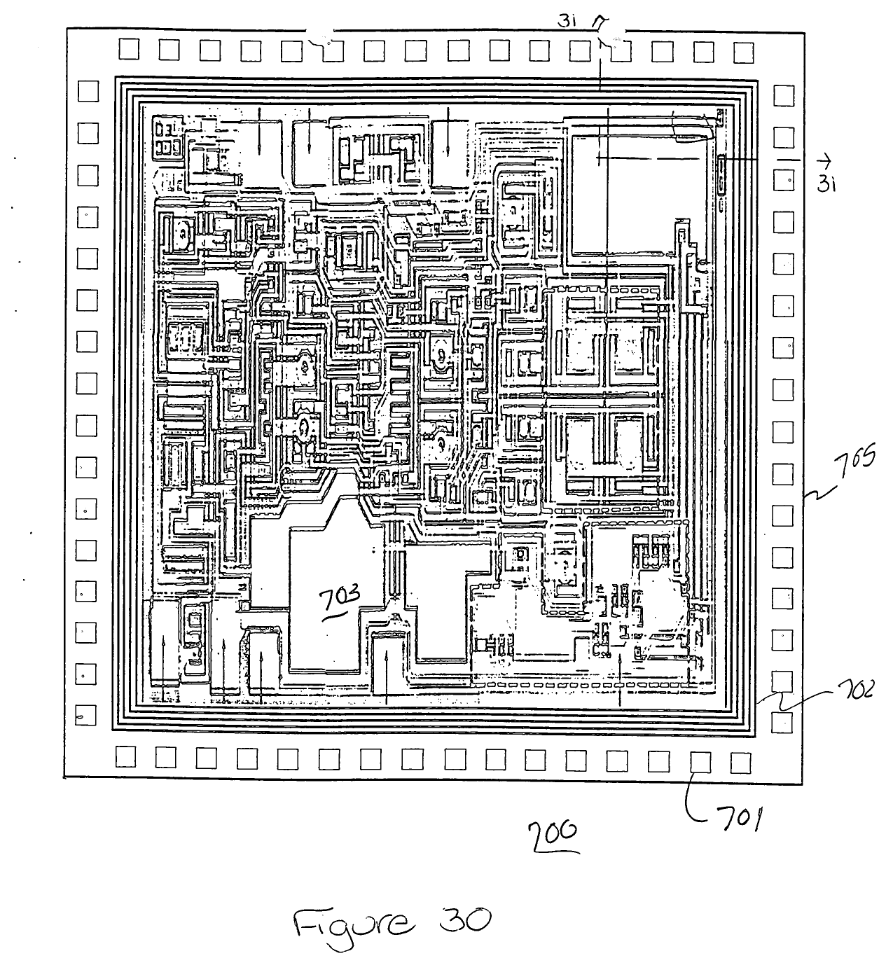

Referring to FIG. 26, in FIG. 26a the device 200 of FIG. 22 is shown. Additional rings can be added to the device 200. For example, FIG. 26b shows device 400 of FIG. 23 having 3 conductors which conductor 413 being connected to conductor ring 402, conductor 411 being connected to conductor ring 403, and conductor 412 being connected to conductor ring 404.

In FIG. 26c device 500 is shown which includes a third ring segment 201b that is located between metal ring 402 and metal ring 407. Metal ring 407 is connected to conductor 416. In FIG. 26d a device 600 is shown having an additional ring, additional segment that includes outer ring 409, a medium 201c located between ring 417. The outer segment 421 provides additional cooling to the inner space 427.

Referring to FIG. 27 not only can the cooling circuit be expanded by the additional segments you can take a group of segments which are called cell 600 and stack the cells by separating each cell 600 by a insulator 601 to obtain an assembled cooling cell 603 as is shown in FIG. 27b.

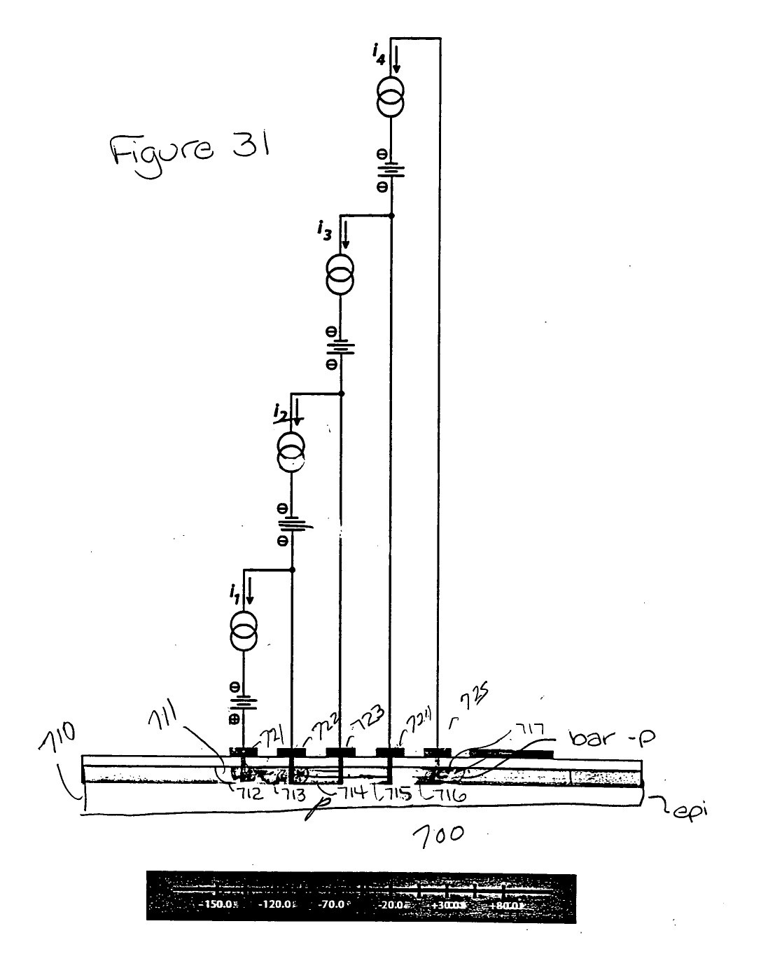

Referring to FIG. 28 there is shown a gas heater 610 that includes a pipe 605 and an assembled cell unit 603. Hot fluids or gas flow into the pipe 605 as is represented by arrow 606 to provide an outflow of cold fluids or gas as is shown by arrow 607. This arrangement can be used as a heat pipe, and would have applications such as air conditioning or even cooling the tundra under the trans-Alaskan pipelines. This would be used to prevent the thermo-frost from melting due to the heat generated by the flow of the trans-Alaskan pipeline.

Providing additional cooling to the assembly 610 could further enhance the device, this embodiment is shown in FIG. 29, to which reference should now be made. There is an outer conductor 621 an inner conductor 622 separated by segment 623. The segment 623 can be any type of medium; or one of the previously described mediums to facilitate what is referred to as force cooling as is shown by the arrow 622. Here again the substance that is cool flows in as indicated by arrow 606 into the pipe 605 and flows out as indicated by the arrow 607. Additionally, the medium 623 could also be air where there is forced cooling provided between the metal sleeve 622 and 621 to remove additional heat and make the thermoelectric cooling cell more efficient (i.e. reducing the K factor of equation (6)).

Referring to FIG. 30 there is shown an application of a cooling model according to the invention to be used with a Pentium microprocessor. The device includes a substrate 705 having a plurality of bonding pads 701, located on the substrate is a Pentium microprocessor 703. Surrounding the microprocessor 703 is a thermo-electric cooling circuit 702 according to the invention. A segment of the thermoelectric cooling circuit 702 is provided as seen from dimension lines 31-31 in FIG. 31. The segment includes a substrate of p-type material 710 and within the p-type material is an implanted N-layer 711. The N-layer is divided into segments 712-717. There are 5 metal conductors 721, 722, 723, 724 and 725 as shown, and run parallel around the microprocessor 703. Each pair of metal conductors is connected to a constant current source. The first segment of 713 has a constant current source that provides current I1 connected between conductors 721-722. The second segment 714 has a constant current source I2 connected between conductor 722 and 723. I2 provides current that is twice the current of I1. Similarly the third segment 715 has a constant current source connected between conductor 723 and conductor 724 and provides a current I3 that is three times the current of I1. Finally, segment 716 has a current source I4 connected between conductor 724 and 725 with I4 being four ties the current of I1. With this configuration the heat that is generated by the microprocessor 703 can be removed. The cooling circuit 702 could be bonded onto a ceramic pad 705 along with the microprocessor 703. By using this configuration microprocessor 703 can be efficiently cool without the necessity of the complex cooling circuits currently being used.

The thermoelectric cooling device of this disclosure can also be used to cool high voltage or high power transistor switches. Example of that is shown in FIG. 32 where there is a smart power device 800. The device 800 includes a semiconductor chip 801 that is segmented into a logic portion 803 and a power mosfet switch 802. Surrounding the power mosfet switch is a cooling circuit 804 similar to the circuit 702 of FIG. 30.

FIG. 33 is an alternate embodiment of the invention in which there is a semiconductor circuit 810 that includes a substrate of an n+ region 821 and an n− region 821. Within the region 821 there are p-rods that go across the semiconductor circuit p-rod 811 p-rod 812, p-rod 813, p-rod 814, p-rod 815 and p-rod 816. Mounted on the semiconductor substrate, in particular on the n region are circuit arrangements 822 over which there is an oxide layer 823. Typically as used herein mounted on a semiconductor substrate would include implants circuits that are implanted and annealed into the semiconductor substrate. With the p-rods running under the circuit areas, the cooling can be effected by connecting currents between p-rods 813 and 812 and connecting a current that is double, between p-rods 812 and 811. Similarly, there can be an II current source connected between p-rod 814 and 815, and an additional current source between p-rod 816 and p-rod 815. The current between p-rod 816 and 815 would be double that between the current provided by the source connected between p-rod 815 and p-rod 814.

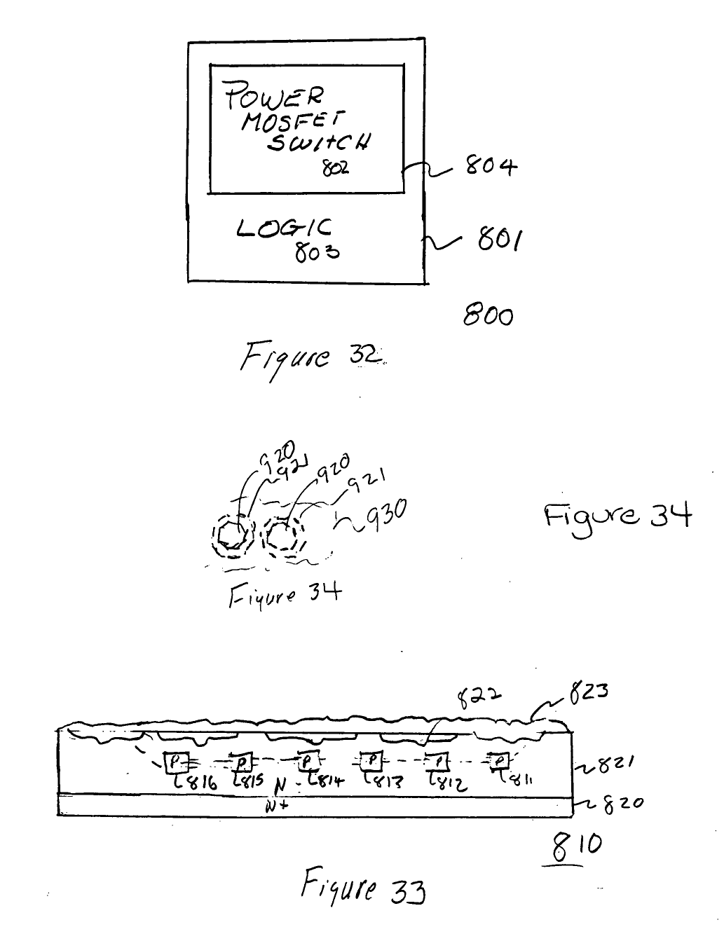

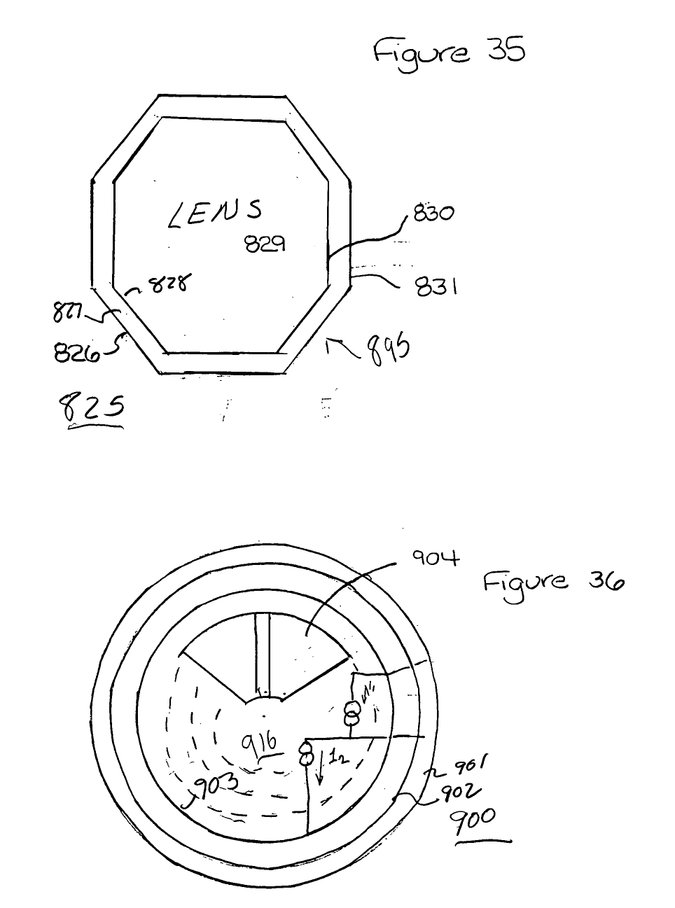

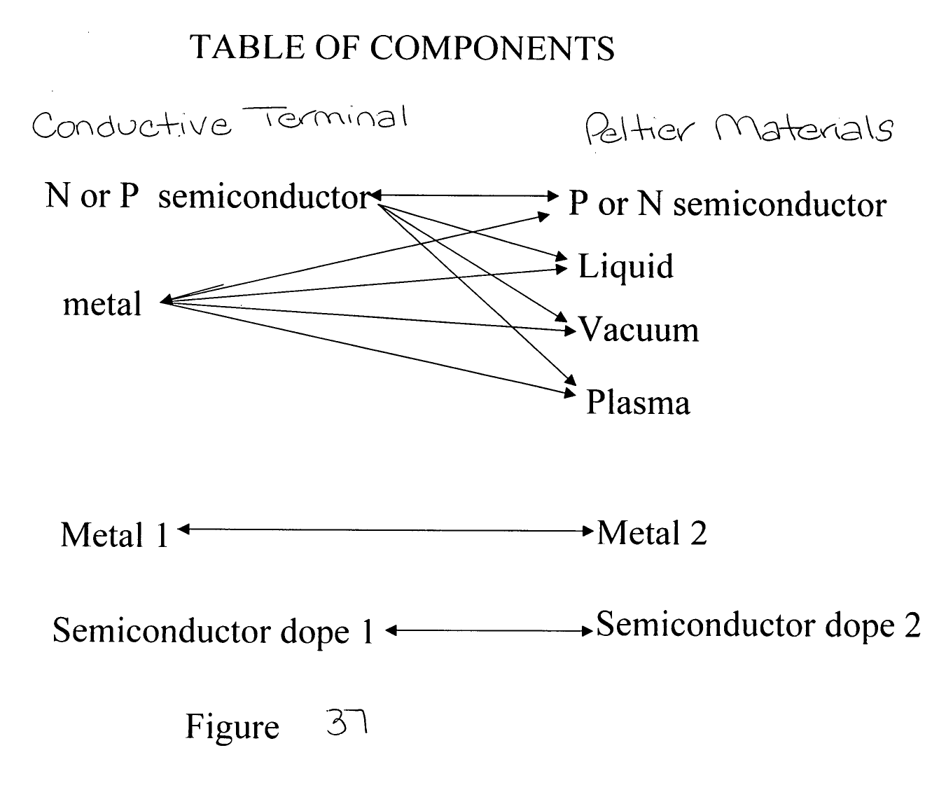

Still an alternative is to cool each transistor cell 920 with a cooling device 921 according to the invention of a Power Transistor 930 than includes a thousand transistor cells. This is illustrated in FIG. 34.

FIG. 35 is a frontal view of an infrared lense 825 that includes a lens area 829 and a cooling circuit 895. The cooling circuit 895 includes an outer conductor 826, an inner conductor 828 separated by a medium such as silicon or glass. Conductors 830 and 831 are used to connect the current source between the metal boundaries 826 and 828.

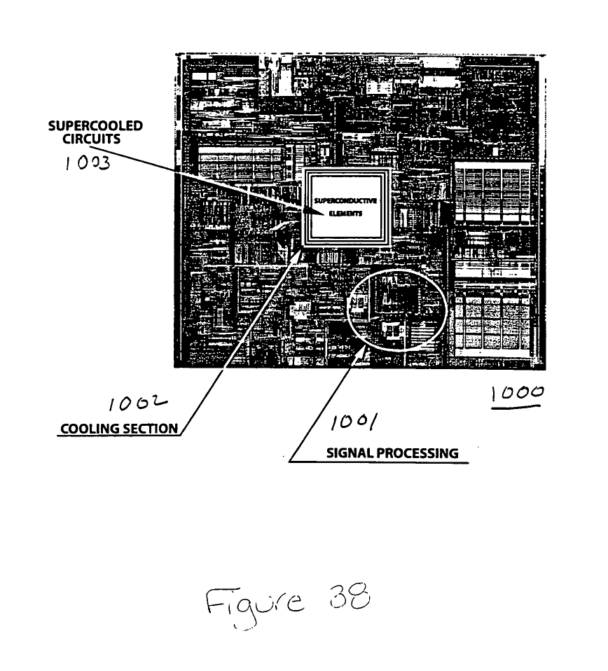

FIG. 36 is a frontal view of an either a spacecraft or an under watercraft that includes the ship, a device 910 having a window 904. There is an outer metal ring, metal 901 and an inner metal ring 902 and the outer skin of the craft 903. A current I1 is connected between the outer ring 901 and the inner ring 902 and a current source 902 is connected between the metal ring 902 and the outer skin of the craft 903 with the current I2 being half that of I1 in situation where the craft 900 if a space craft because it would be desired to cool the space craft from the heating effect caused by the sun, and the opposite would be true in the event of the craft 900 and the craft 900 is an undersea craft as would be desired to warm the craft if it were the deep ocean. The medium in the situation of space is of course a vacuum or very limited air, whereas the medium would be water when used as an undersea craft.

There are many combinations of materials that could be used to fabricate the cooling device that is discussed in the previous sections. FIG. 37 is a table which provides examples of the different combinations that can be used.

FIG. 38 illustrate an example of a Superconducting Quantum Interface Device, SQUID, with a high efficiency cooling system as taught herein. The device is a circuit such as high frequency radio receiver 1000 and includes a signal processor 1001, a cooling section such as that taught in FIG. 30 cooling superconductive elements 1003. The basic operation of SQUIDs is disclosed in the August 1994 article by John Clarke in Scientific American, entitled “SQUIDs” on pages 46 through 52 also in the February 1993 article by Bishop, Grmmel and Huse entitled “Resistance in High-Temperature Superconductors” also in Scientific American pages 48 through 55. Both articles are incorporated herein by reference.

1. A semiconductor device comprising:
a semiconductor substrate of a first conductivity type and having a predefined periphery and a first surface;
a semiconductor circuit located on the first surface within the predefined periphery; and
a cooling circuit located around the semiconductor circuit on the first surface, the cooling circuit includes a cooling cell comprising a semiconductor area of a second conductivity type and first and second conductors in parallel alignment and located within the semiconductor area and spaced apart from each other by a segment of the semiconductor area, the segment having a predetermined width, L, with the width L being predetermined so that the segment becomes substantially depleted when the cooling circuit is in operation.

2. The semiconductor device according to claim 1 wherein the cooling circuit further comprises: a current sources operatively connected to the first and second conductor to facilitate the transfer heat from a first side of the cooling cell to a second side of the cooling cell.

3. The semiconductor device according to claim 1 wherein the semiconductor circuit is a single transistor cell and the cooling cell surrounds the transistor cell.

4. The semiconductor device according to claim 3 wherein the single transistor cell has a polygonal shape when viewed from the first surface and the cooling cell surrounds the transistor cell and also has a polygonal shape.

5. The semiconductor device according to claim 3 wherein the single transistor cell has a circular shape when viewed from the first surface and the cooling cell surrounds the transistor cell and also has a circular shape.

6. The semiconductor device according to claim 3 wherein the single transistor cell has a mesh shape when viewed from the first surface and the cooling cell surrounds the transistor cell.

7. The semiconductor device according to claim 1 wherein the cooling circuit further comprises: a second cooling cell of a second semiconductor segment and a third conductor with a first side of the second semiconductor segment being adjacent to the third conductor and a second side of the second semiconductor segment being adjacent to the second conductor.

8. The semiconductor device according to claim 7 wherein the cooling circuit further comprises:
a first current sources operatively connected to the first and second conductor to facilitate the transfer heat from a first side of the semiconductor segment to a second side of the semiconductor segment; and
a second current sources operatively connected to the second and third conductor to facilitate the transfer heat from the first side of the second semiconductor segment to the second side of the second semiconductor segment.

9. The semiconductor device according to claim 8 wherein the current from the second current source is one half the current from the first current source.

10. The semiconductor device according to claim 1 wherein the semiconductor circuit is a plurality power mosfet transistor cells and the cooling circuit surrounds the transistor cells.

11. The semiconductor device according to claim 1 wherein the semiconductor circuit is a microprocessor circuit and the cooling circuit surrounds the microprocessor.

12. The semiconductor device according to claim 1 wherein the semiconductor circuit is a memory circuit and the cooling circuit surrounds the memory circuit.

13. A semiconductor device comprising:
a semiconductor substrate of a first conductivity type and having a predefined periphery and a first surface;
a semiconductor circuit located on the first surface within the predefined periphery; and
a cooling circuit located between semiconductor circuit and the predefined periphery on the first surface, the cooling circuit includes a semiconductor area of a second conductivity type and a plurality of N conductors in parallel alignment and located within the semiconductor area, the semiconductor area being a plurality of N+1 segments with each segment being separated from other segments by a member of the plurality of conductors.

14. The semiconductor device according to claim 13 wherein the cooling circuit further comprises:
a plurality of N−1 current sources operatively connected to the cooling circuit.

15. The semiconductor device according to claim 13 wherein the cooling circuit has a polygonal shape when viewed from the first surface.

16. The semiconductor device according to claim 15 wherein the cooling circuit further comprises:
a plurality of N−1 current sources operatively connected to the plurality of N conductors with a first current source being connected between a first conductor and a second conductor of the plurality of conductors and a second current source being connected between the second conductor and a third conductor of the plurality of N conductor and each of any remaining current sources of the plurality of current source being like wise connect through an N^{th}−1 current source being connected between the N^{th}−1 conductor and the N^{th} conductor.

17. The semiconductor device according to claim 16 wherein the cooling circuit cools the semiconductor circuit and the first conductor is located between a first segment and a second segment of the plurality of N+1 segments and the second conductor is located between the second segment and a third segment of the plurality of N+1 segments and each of any remaining conductors of the plurality of N conductors being likewise located through an N^{th} conductor being located being located between the N^{th} segment and the N^{th}+1 segment of the plurality of N+1 segments.

18. The semiconductor device according to claim 17 wherein each segment has a heat field depletion area and an electric field depletion area with the heat depletion area being located on a first side of a segment nearest the semiconductor circuit and the electric depletion area being located on a side across the segment from the first side and the width of the segment being selected so that the heat depletion area is in contact with the electric depletion area.

19. The semiconductor device according to claim 17 wherein the first segment is the segment nearest the semiconductor circuit and the second current source provides a current twice the current of the first current and similarly each additional current source of the plurality of N−1 current sources providing a current that is multiple of the first current source with a current source connected to a conductor nearer the semiconductor circuit providing a current that is less than a current provided from an adjacent current source connected to a conductor further from the semiconductor circuit such that the largest amount of current being provided by the N−1 current source providing N−1 times the current of the first current source.

20. The semiconductor device according to claim 13 with the semiconductor area being of an annular shape.

21. The semiconductor device according to claim 20 wherein the cooling circuit further comprises:
a plurality of N−1 current sources operatively connected to the plurality of N conductors with a first current source being connected between a first conductor and a second conductor of the plurality of conductors and a second current source being connected between the second conductor and a third conductor of the plurality of N conductor and each of any remaining current sources of the plurality of current source being like wise connect through an N^{th}−1 current source being connected between the N^{th}−1 conductor and the N^{th} conductor.

22. The semiconductor device according to claim 20 wherein the cooling circuit cools the semiconductor circuit and the first conductor is located between a first segment and a second segment of the plurality of N+1 segments and the second conductor is located between the second segment and a third segment of the plurality of N+1 segments and each of any remaining conductors of the plurality of N conductors being likewise located through an N^{th} conductor being located being located between the N^{th} segment and the N^{th}+1 segment of the plurality of N+1 segments.

23. The semiconductor device according to claim 22 wherein each segment has a heat field depletion area and an electric field depletion area with the heat depletion area being located on a first side of a segment nearest the semiconductor circuit and the electric depletion area being located on a side across the segment from the first side and the width of the segment being selected so that the heat depletion area is in contact with the electric depletion area.

24. The semiconductor device according to claim 22 wherein the first segment is the segment nearest the semiconductor circuit and the second current source provides a current twice the current of the first current and similarly each additional current source of the plurality of N−1 current sources providing a current that is multiple of the first current source with a current source connected to a conductor nearer the semiconductor circuit providing a current that is less than a current provided from an adjacent current source connected to a conductor further from the semiconductor circuit such that the largest amount of current being provided by the N−1 current source providing N−1 times the current of the first current source.

25. A semiconductor device comprising:
a semiconductor substrate of a first conductivity type and having a predefined periphery and a first surface;
a semiconductor circuit located on the first surface within the predefined periphery; and
a cooling circuit laterally surrounding the semiconductor circuit on the first surface, the cooling circuit includes a semiconductor area of a second conductivity type and a plurality of N conductors in parallel alignment and located within the semiconductor area, the semiconductor area being a plurality of N+1 segments with each segment being separated from other segments by a member of the plurality of conductors.

26. The semiconductor device according to claim 25 wherein the cooling circuit further comprises:
a plurality of N−1 current sources operatively connected to the cooling circuit.

27. The semiconductor device according to claim 27 wherein the cooling circuit has a polygonal shape when viewed from the first surface.

28. The semiconductor device according to claim 27 wherein the cooling circuit further comprises:
a plurality of N−1 current sources operatively connected to the plurality of N conductors with a first current source being connected between a first conductor and a second conductor of the plurality of conductors and a second current source being connected between the second conductor and a third conductor of the plurality of N conductor and each of any remaining current sources of the plurality of current source being like wise connect through an N^{th}−1 current source being connected between the N^{th}−1 conductor and the Nth conductor.

29. The semiconductor device according to claim 28 wherein the cooling circuit cools the semiconductor circuit and the first conductor is located between a first segment and a second segment of the plurality of N+1 segments and the second conductor is located between the second segment and a third segment of the plurality of N+1 segments and each of any remaining conductors of the plurality of N conductors being likewise located through an N^{th} conductor being located being located between the N^{th} segment and the N^{th}+1 segment of the plurality of N+1 segments.

30. The semiconductor device according to claim 29 wherein each segment has a heat field depletion area and an electric field depletion area with the heat depletion area being located on a first side of a segment nearest the semiconductor circuit and the electric depletion area being located on a side across the segment from the first side and the width of the segment being selected so that the heat depletion area is in contact with the electric depletion area.

31. The semiconductor device according to claim 29 wherein the first segment is the segment nearest the semiconductor circuit and the second current source provides a current twice the current of the first current and similarly each additional current source of the plurality of N−1 current sources providing a current that is multiple of the first current source with a current source connected to a conductor nearer the semiconductor circuit providing a current that is less than a current provided from an adjacent current source connected to a conductor further from the semiconductor circuit such that the largest amount of current being provided by the N−1 current source providing N−1 times the current of the first current source.

32. The semiconductor device according to claim 25 with the semiconductor area being of an annular shape.

33. The semiconductor device according to claim 32 wherein the cooling circuit further comprises:
a plurality of N−1 current sources operatively connected to the plurality of N conductors with a first current source being connected between a first conductor and a second conductor of the plurality of conductors and a second current source being connected between the second conductor and a third conductor of the plurality of N conductor and each of any remaining current sources of the plurality of current source being like wise connect through an N^{th}−1 current source being connected between the N^{th}−1 conductor and the Nth conductor.

34. The semiconductor device according to claim 33 wherein the cooling circuit cools the semiconductor circuit and the first conductor is located between a first segment and a second segment of the plurality of N+1 segments and the second conductor is located between the second segment and a third segment of the plurality of N+1 segments and each of any remaining conductors of the plurality of N conductors being likewise located through an N^{th} conductor being located being located between the N^{th} h segment and the N^{th}+1 segment of the plurality of N+1 segments.

35. The semiconductor device according to claim 34 wherein each segment has a heat field depletion area and an electric field depletion area with the heat depletion area being located on a first side of a segment nearest the semiconductor circuit and the electric depletion area being located on a side across the segment from the first side and the width of the segment being selected so that the heat depletion area is in contact with the electric depletion area.

36. The semiconductor device according to claim 34 wherein the first segment is the segment nearest the semiconductor circuit and the second current source provides a current twice the current of the first current and similarly each additional current source of the plurality of N−1 current sources providing a current that is multiple of the first current source with a current source connected to a conductor nearer the semiconductor circuit providing a current that is less than a current provided from an adjacent current source connected to a conductor further from the semiconductor circuit such that the largest amount of current being provided by the N−1 current source providing N−1 times the current of the first current source.
